(19) United States
(12) Patent Application Publication
(10) Pub. No.: US 2021/0367174 A1
(43) Pub. Date: Nov. 25, 2021

(54) ORGANIC SOLAR CELL INCLUDING DUAL LAYER TYPE CHARGE TRANSPORT LAYER HAVING ENHANCED PHOTOSTABILITY, AND MANUFACTURING METHOD THEREFOR

(71) Applicant: KONKUK UNIVERSITY INDUSTRIAL COOPERATION CORP, Gwangjin-gu, Seoul (KR)

(72) Inventors: Doo Kyung MOON, Seocho-gu, Seoul (KR); Yong Woon HAN, Hanam-si, Gyeonggi-do (KR); Sung Jae JEON, Dongjak-gu, Seoul (KR)

(21) Appl. No.: 17/257,488

(22) PCT Filed: Jul. 4, 2019
(86) PCT No.: PCT/KR2019/008240

§ 371 Date: Dec. 31, 2020

(30) Foreign Application Priority Data
Jul. 4, 2018 (KR) 10-2018-0077637

(51) Int. Cl. H01L 51/42; H01L 51/00

(52) U.S. Cl. CPC H01L 51/422; H01L 51/0001; H01L 2251/303; H01L 51/0043; H01L 51/0037

(57) ABSTRACT

An organic solar cell having a structure including a dual layer type charge transport layer, which has an ultraviolet blocking layer, is provided. The organic solar cell has a dual layer charge transport layer by including a photostable charge transport layer on one surface or both surfaces of a photoactive layer, thereby having enhanced charge transport capability within the solar cell, improved photostability without an external protection film, and excellent durability. In addition, a method for manufacturing an organic solar cell is provided which forms a photostability charge transport layer on one surface or both surfaces of a photoactive layer, thereby manufacturing a solar cell, which can be stable when exposed to ultraviolet light during electrode formation and has a highly efficient and photostability-enhanced structure in a manufacturing process without a step of attaching a protection glass and a protection film.

### TECHNICAL FIELD

The present invention relates to an organic solar cell in a structure including a dual layer type charge transport layer having an ultraviolet blocking layer and a manufacturing method thereof, and more particularly, an organic solar cell with enhanced photostability by introducing a photostable charge transport layer and a charge transport layer as a dual layer and a manufacturing method thereof.

### BACKGROUND ART

Organic photovoltaics are devices which convert light energy into electrical energy and have characteristics in which both an organic semiconductor and an inorganic semiconductor are used as a photoactive layer and a buffer layer. The organic photovoltaics can be manufactured by a simplified method using organic and inorganic semiconductors with which a solution process is applicable and applied to the field of flexible organic electronic devices, and thus the organic photovoltaics are receiving attention as a next generation power source. In particular, the organic semiconductor has advantages such as an excellent optical character and ease of a process and disadvantages such as a limited charge mobility characteristic and vulnerability to ultraviolet light and moisture, and the disadvantages can be solved by introducing an inorganic semiconductor, and thus it is possible to implement an organic photoelectric device with high efficiency and high stability using an excellent charge mobility characteristic of the inorganic semiconductor.

A structure of an organic solar cell to be implemented is generally as follows. The organic solar cell includes a photoactive layer which has a photovoltaic characteristic to convert light energy into electric energy, a charge transport layer which transfers generated charges to an electrode, and the electrode which receives the transferred charges and transfers the received charges to an external circuit. Here, since the charge transport layer serves to extract and transfer the charges generated in the photoactive layer to the electrode, the charge transport layer is essentially introduced so as to improve efficiency of the organic solar cell.

Barium fluoride (BaF₂) or lithium fluoride (LiF), which is an ion bondable metal capable of being deposited through a thermal deposition process, is generally used as an electron transport layer of the charge transport layer, which extracts and transfers electrons to a negative electrode (cathode), and zinc oxide (ZnO) and titanium dioxide (TiO₂) capable of being deposited through a sol-gel process are introduced into a solution process.

Molybdenum oxide (MoO₃), vanadium pentoxide (V₂O₅), or tungsten oxide (WO₃), which is a transition metal capable of being deposited through a thermal deposition process, is mainly used as a hole transport layer of the charge transport layer, which extracts and transfers holes to a positive electrode (anode), and a poly(3,4-ethylene dioxythiophene)-poly(4-styrenesulfonate) (PEDOT:PSS) polymer capable of being deposited through a solution process is mainly used.

In order to commercialize solar cells, flexible devices and large area devices should be manufactured by applying the solar cells to substrates such as poly(ethylene terephthalate) (PET) substrates, poly(ethylene naphthalate) (PEN) substrates, and polyimide (PI) substrates through a solution process and a roll-to-roll process, but a method of forming a film through deposition (thermal evaporation, deposition) is not suitable for commercialization due to low uniformity. Thus, a high-efficiency solar cell should be manufactured by introducing a charge transport layer through a solution process, and ultraviolet light and moisture should be blocked by performing an encapsulation process after the manufacturing to secure stability.

Most of the existing techniques are in the form of bonding a protective glass and a protective film to an outer side of a solar cell after manufacturing the solar cell by introducing a general charge transport layer and a general photoactive layer. However, costs for an additional process occur, and as the solar cell becomes larger, sizes of the protective glass and the protective film required for the large solar cell are proportionally increased such that there is a problem of being uneconomical.

### DISCLOSURE

### Technical Problem

The present invention is directed to providing an organic solar cell having high resistance to ultraviolet light by introducing a charge transport layer with enhanced photostability.

The present invention is also directed to providing a method of manufacturing a solar cell with enhanced photostability by introducing a charge transport layer having an ultraviolet light absorption characteristic in the form of a dual layer during a process of manufacturing the organic solar cell.

### Technical Solution

One aspect of the present invention provides an organic solar cell including a first electrode, a first charge transport layer, a photoactive layer, a second charge transport layer, and a second electrode, wherein a photostable charge transport layer is included in one surface or two surfaces of the photoactive layer, and the photostable charge transport layer contains a metal oxide.

Another aspect of the present invention provides a method of manufacturing an organic solar cell, which includes mixing a metal oxide precursor with a solvent and preparing a solution for a photostable charge transport layer, and applying the solution for a photostable charge transport layer onto one surface or two surfaces of the photoactive layer to form a photostable charge transport layer.

### Advantageous Effects

In accordance with an organic solar cell according to the present invention, a photostable charge transport layer is included in one surface or two surfaces of the photoactive layer, and thus a charge transport layer of a dual layer structure is included so that the organic solar cell with enhanced charge transport capability, improved photostability without an external protective film, and high durability can be provided.

In addition, the photostable charge transport layer according to the present invention can be uniformly formed as a thin film through a solution process such as a spin-coating, inkjet printing, or slot-die coating process. When a large-area solar cell and a solar module are manufactured, the photostable charge transport layer can be stable with respect to ultraviolet (UV) light used in the formation of an electrode, and it is possible to manufacture the solar cell with a structure of high efficiency and enhanced photostability without a process of bonding a protective glass and a protective film so that there is an advantage capable of significantly contributing to commercialization of a next-generation solar cell.

### DESCRIPTION OF DRAWINGS

FIG. 1 illustrates schematic diagrams illustrating a structure of an organic solar cell according to the present invention.

FIG. 2 illustrates an image (see FIG. 2A) of a thin film after applying a photoactive layer according to one embodiment, an image (see FIG. 2B) of a thin film after applying the photoactive layer and introducing a photostable charge transport layer on the photoactive layer according to the embodiment, and an image (see FIG. 2C) of a thin film after applying the photostable charge transport layer and introducing a hole transport layer on the photostable charge transport layer according to the embodiment.

FIG. 3 illustrates schematic diagrams illustrating a structure of an organic solar cell according to one embodiment, wherein FIG. 3A illustrates an organic solar cell (based on an SMD2:ITIC-Th photoactive layer) manufactured without introducing a photostable charge transport layer, FIG. 3B illustrates an organic solar cell (based on the SMD2:ITIC-Th photoactive layer) manufactured by introducing a photostable charge transport layer between a photoactive layer and a hole transport layer, FIG. 3C illustrates an organic solar cell (based on the SMD2:ITIC-Th photoactive layer) manufactured by introducing the photostable charge transport layer between the hole transport layer and a second electrode, FIG. 3D illustrates an organic solar cell (based on the SMD2:ITIC-Th photoactive layer) manufactured by introducing the photostable charge transport layer between an electron transport layer and the photoactive layer, FIG. 3E illustrates an organic solar cell (based on the SMD2:ITIC-Th photoactive layer) manufactured by introducing the photostable charge transport layer between a first electrode and the electron transport layer, and FIG. 3F illustrates an organic solar cell (based on the SMD2:ITIC-Th photoactive layer) manufactured by introducing the photostable charge transport layer between the electron transport layer and the photoactive layer and between the photoactive layer and the hole transport layer.

FIG. 4 illustrates schematic diagrams illustrating a structure of an organic solar cell according to one embodiment, wherein FIG. 4A illustrates an organic solar cell (based on a P(Cl):ITIC-Th photoactive layer) manufactured without introducing a photostable charge transport layer, FIG. 4B illustrates an organic solar cell (based on the P(Cl):ITIC-Th photoactive layer) manufactured by introducing a photostable charge transport layer between a photoactive layer and a hole transport layer, FIG. 4C illustrates an organic solar cell (based on the P(Cl):ITIC-Th photoactive layer) manufactured by introducing the photostable charge transport layer between the hole transport layer and a second electrode, FIG. 4D illustrates an organic solar cell (based on the P(Cl):ITIC-Th photoactive layer) manufactured by introducing the photostable charge transport layer between an electron transport layer and the photoactive layer, FIG. 4E illustrates an organic solar cell (based on the P(Cl):ITIC-Th photoactive layer) manufactured by introducing the photostable charge transport layer between a first electrode and the electron transport layer, and FIG. 4F illustrates an organic solar cell (based on the P(Cl):ITIC-Th photoactive layer) manufactured by introducing the photostable charge transport layer between the electron transport layer and the photoactive layer and between the photoactive layer and the hole transport layer.

FIG. 5 illustrates graphs showing measurement results of X-ray photoelectron spectroscopy (XPS) depth profiling before and after heat treatment of a photostable charge transport layer according to one embodiment, wherein FIG. 5A is a graph showing a result of the XPS depth profiling before heat treatment at a temperature of 100° C., and FIG. 5B is a graph showing a result of the XPS depth profiling after the heat treatment at the temperature of 100° C.

FIG. 6 illustrates graphs showing results of XPS measurement of a photostable charge transport layer according to one embodiment, wherein FIG. 6A is a graph showing an XPS result of a sample manufactured after a hole transport layer is introduced, and FIG. 6B is a graph showing an XPS result of a sample manufactured after a photostable charge transport layer and the hole transport layer are introduced.

FIG. 7 illustrates photographs showing results captured by an atomic force microscope (AFM) of a sample according to one embodiment, wherein an upper photograph of FIG. 7 shows a measurement result of the sample manufactured after the hole transport layer is introduced, and a lower photograph of FIG. 7 shows a measurement result of the sample manufactured after the photostable charge transport layer and the hole transport layer are introduced.

FIG. 8A is a graph showing a measurement result of a high binding energy portion of an electrical characteristic of the sample manufactured after an Ag electrode, the photostable charge transport layer, and the hole transport layer are introduced, and FIG. 8B is a graph showing a measurement result of a lower binding energy portion of the electrical characteristic of the sample manufactured after the Ag electrode, the photostable charge transport layer, and the hole transport layer are introduced.

FIG. 9 is an energy level diagram derived through measurement results of the electrical characteristic of the sample manufactured after the Ag electrode, the photostable charge transport layer, and the hole transport layer according to one embodiment.

FIG. 10 illustrates graphs showing simulation results of an optical characteristic of a sample according to one embodiment, wherein FIG. 10A is a graph showing an optical prediction result derived through the simulation result of the optical characteristic after the photoactive layer and the hole transport layer are introduced, and FIG. 10B is a graph showing an optical prediction result derived through the simulation result of the optical characteristic after the photoactive layer, the photostable charge transport layer, and the hole transport layer are introduced.

FIG. 11 is a graph showing a glass substrate-based ultraviolet (UV) measurement result of the sample manufactured after the photostable charge transport layer and the hole transport layer are introduced according to one embodiment.

FIG. 12 is a graph showing a photoactive layer-based UV measurement result of the sample in a forward direction, which is manufactured after the photostable charge transport layer and the hole transport layer according to one embodiment.

FIG. 13 is a graph showing a photoactive layer-based UV measurement result of the sample in a backward direction, which is manufactured after the photostable charge transport layer and the hole transport layer according to one embodiment.

FIG. 14 illustrates graphs showing long-term stability characteristics of the organic solar cells according to one embodiment, wherein FIG. 14A is a graph showing long-term stability characteristics of the organic solar cells (based on the SMD2: ITIC-Th photoactive layer) manufactured after the photostable charge transport layer and the hole transport layer are introduced, and FIG. 14B is the long-term stability characteristics of the organic solar cell (based on SMD2:ITIC-Th photoactive layer) manufactured after the introduction of the photostable charge transport layer for each location.

FIG. 15 illustrates graphs showing long-term stability characteristics of the organic solar cells according to one embodiment, wherein FIG. 15A is a graph showing a long-term stability characteristic of the organic solar cell (based on the P(Cl):ITIC-Th photoactive layer) manufactured after the photostable charge transport layer and the hole transport layer are introduced, and FIG. 15B is a graph showing a long-term stability characteristic of the organic solar cell (based on the P(Cl):ITIC-Th photoactive layer) manufactured after the photostable charge transport layer is introduced for each location.

FIG. 16 illustrates images illustrating copolymers included in a photoactive layer according to one embodiment.

### MODES OF THE INVENTION

The present invention may be modified into various forms and may have a variety of example embodiments, and, therefore, specific embodiments will be illustrated in the accompanying drawings and described in detail.

The embodiments, however, are not to be taken in a sense which limits the present invention to the specific embodiments and should be construed to include modifications, equivalents, or substituents within the spirit and technical scope of the present invention. Also, in the following description of the present invention, when it is determined that a detailed description of a known related art obscures the gist of the present invention, the detailed description thereof will be omitted.

The present invention provides an organic solar cell including a first electrode, a first charge transport layer, a photoactive layer, and a second charge transport layer, and a second electrode, a photostable charge transport layer is included in one surface or two surfaces of the photoactive layer, and the photostable charge transport layer contains a metal oxide.

For example, the metal oxide contained in the photostable charge transport layer may include one or more selected from the group consisting of tungsten oxide, molybdenum oxide, cobalt oxide, and copper oxide. Specifically, the metal oxide may include tungsten oxide, molybdenum oxide, cobalt oxide, or copper oxide. More specifically, the metal oxide may be tungsten oxide or molybdenum oxide. The metal oxide may have a characteristic of absorbing ultraviolet light to improve photostability of an organic solar cell containing the metal oxide.

As another example, the photostable charge transport layer may contain a metal oxide in an amount of 1 to 10⁴ g/cm³. More specifically, the photostable charge transport layer may contain a metal oxide in an amount of 10 to 10⁴ g/cm³, 10² to 10⁴ g/cm³, or 10³ to 10⁴ g/cm³. Since the metal oxide in the above amount is included, the photostable charge transport layer may effectively absorb ultraviolet light.

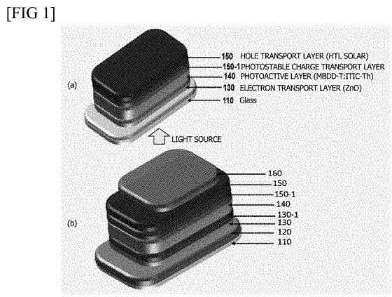

As an example, in the organic solar cell according to the present invention, the photostable charge transport layer may be involved at a position between the first charge transport layer and the photoactive layer, involved at a position between the second charge transport layer and the photoactive layer, or involved at each of the above positions. Specifically, the organic solar cell of the present invention may have a structure in which the first charge transport layer, the photostable charge transport layer, the photoactive layer, and the second charge transport layer are stacked, a structure in which the first charge transport layer, the photoactive layer, the photostable charge transport layer, and the second charge transport layer are stacked, or a structure in which the first charge transport layer, the first photostable charge transport layer, the photoactive layer, the second photostable charge transport layer, and the second charge transport layer are stacked. More specifically, as shown in FIG. 1A, the organic solar cell may have a structure in which a transparent substrate 110, a first charge transport layer 130, a photoactive layer 140, a photostable charge transport layer 150-1, and the second charge transport layer are stacked from a lower portion. In this case, the first charge transport layer may be an electron transport layer, the second charge transport layer may be a hole transport layer, and the reverse of the above descriptions may also be included.

As an example, each of the first and second charge transport layers of the organic solar cell according to the present invention may further include an electrode on one surface thereof. Specifically, in the organic solar cell, a first electrode may be formed on the first charge transport layer, and a second electrode may be formed on the second charge transport layer. More specifically, as shown in FIG. 1B, the organic solar cell may be formed in a structure in which the transparent substrate 110, a first electrode 120, the first charge transport layer 130, a first photostable charge transport layer 130-1, the photoactive layer 140, a second photostable charge transport layer 150-1, a second charge transport layer 150, and a second electrode 160 are stacked. In this case, the first charge transport layer may be an electron transport layer, and the second charge transport layer may be a hole transport layer. Alternatively, the first charge transport layer may be a hole transport layer, and the second charge transport layer may be an electron transport layer.

The organic solar cell according to the present invention includes the photostable charge transport layer to absorb ultraviolet light exposed when the organic solar cell is manufactured and ultraviolet light exposed after the organic solar cell is manufactured so that photostability of the organic solar cell with respect to external light may be improved.

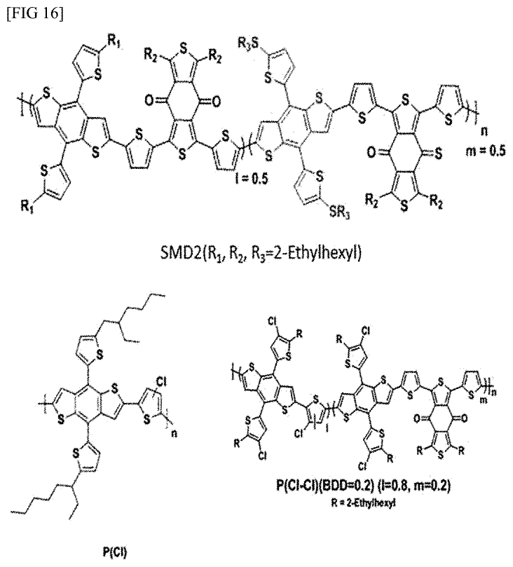

Specifically, the photoactive layer may include one or more selected from the group consisting of poly[[4, 8-bis[(2-ethylhexyl)oxy]benzo[1,2-b :4,5-b′]dithiophene-2,6-diyl][3-fluoro-2-[(2-ethylhexyl)carbonyl]thieno[3,4-b]thiophendiyl]](PTB7), poly([2,6′-4,8-di(5-ethylhexylthienyl)benzo[1,2-b:3,3-b]dithiophene]{ 3-fluoro-2[(2-ethyl Hexyl)carbonyl]thieno[3,4-b]thiophendiyl})(PTB7-Th), poly[(2,6-(4,8-bis(5-(2-ethylhexyl)thiophene)-2-yl)-benzo[1,2-b :4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)](PBDB-T), an SMD2 copolymer, a P(Cl)-based copolymer, and a P(Cl—Cl)-based copolymer as an electron donor. Specifically, the photoactive layer may include poly[[4,8-bis[(2-ethylhexyl)oxy]benzo[1,2-b:4,5-bldithiophene-2,6-diyl][3-fluoro-2-[(2-ethylhexyl)carbonyl]thieno[3,4-b]thiophendiyl]](PTB 7), poly([2,6′-4,8-di(5-ethylhexylthienyl)benzo[1,2-b:3,3-b]dithiophene]{3-fluoro-2[(2-ethyl Hexyl)carbonyl]thieno[3,4-b]thiophendiyl})](PTB7-Th), poly[(2,6-(4,8-bis(5-(2-ethylhexyl)thiophene)-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4, 8-dione)](PBDB-T), an SMD2 copolymer, a P(Cl)-based copolymer, or a P(Cl—Cl)-based copolymer as an electron donor. More specifically, the photoactive layer may include an SMD2 copolymer, a P(Cl)-based copolymer, a P(Cl—Cl)-based copolymer as an electron donor. Specific structures of an SMD2 copolymer, a P(Cl)-based copolymer, and a P(Cl—Cl)-based copolymer are shown in FIG. 16.

In addition, the photoactive layer may include one or more selected from the group consisting of phenyl-C61-butyrate methyl ester (phenyl-C61-butyric acid methyl ester or methyl[6,6]-phenyl-c₆₁-butyrate) (PC₆₁BM), phenyl-C₇₁-butyrate methyl ester (phenyl-C71-butyric acid methyl ester or methyl[7,7]-phenyl-C71-butyrate) (PC71BM), 3,9-bis(2-methylene-(3-(1,1-dicyanomethylene)-indaone))-5,5, 11,11-tetrakis(4-hexylphenyl)-dithieno[2,3-d:2′,3′-d′]-s-indaceno[1,2-b:5,6-b′]dithiophene (ITIC), 3,9-bis(2-methylene-(3-(1,1-dicyanomethylene)-indaone))-5, 5,11, 11-tetrakis(5-hexylthienyl)-dithieno[2,3-d:2′,3′-d′]-s-indaceno[1,2-b:5,6-b′]dithiophene (ITIC-Th), 2,7-bis(3-dicyanomethylene-2Z-methylene-indan-1-one)-4,4, 9,9-tetrahexyl-4,9-dihydro-s-indaceno[1,2-b:5,6-b′]dithiophene (IDIC), and 3,9-bis(2-methylene-((3-(1,1-dicyanomethylene)-6,7-difluoro)-indaone))-5,5,11,11-tetrakis(4-hexylphenyl)-dithieno[2,3-d:2′,3′-d′]s-indaceno[1,2-b:5,6-b′]dithiophene (ITIC-4F) as an electron acceptor. Specifically, the photoactive layer may be phenyl-C₆₁-butyrate methyl ester (phenyl-C61-butyric acid methyl ester or methyl[6,6]-phenyl-c61-butyrate) (PC₆₁BM), phenyl-C₇₁-butyrate methyl ester (phenyl-C71-butyric acid methyl ester or methyl[7,7]-phenyl-C71-butyrate) (PC71BM), 3,9-bis(2-methylene-(3-(1,1-dicyanomethylene)-indaone))-5,5,11,11-tetrakis(4-hexylphenyl)-dithieno[2,3-d:2′,3′-d′]-s-indaceno[1,2-b:5,6-b′]dithiophene (ITIC), 3,9-bis(2-methylene-(3-(1,1-dicyanomethylene)-indaone))-5, 5, 11, 11-tetrakis(5-hexylthienyl)-dithieno[2,3-d:2′,3 ′-d′]-s-indaceno[1,2-b:5,6-b′]dithiophene (ITIC-Th), 2,7-bis(3-dicyanomethylene-2Z-methylene-indan-1-one)-4,4,9,9-tetrahexyl-4,9-dihydro-s-indaceno[1,2-b:5,6-b′]dithiophene (IDIC), or 3,9-bis(2-methylene-((3-(1,1-dicyanomethylene)-6,7-difluoro)-indaone))-5, 5, 11,11-tetrakis(4-hexylphenyl)-dithieno[2,3-d:2′,3′-d′]-s-indaceno[1,2-b:5,6-b]dithiophene (ITIC-4F).

As an example, materials of the first and second charge transport layers are not particularly limited as long as the materials are used for the hole transport layer and/or the electron transport layer. Specifically, the first charge transport layer may include an N-type charge transport organic/inorganic compound, and the second charge transport layer may include a P-type charge transport organic/inorganic compound. On the contrary, the first charge transport layer may include an N-type charge transport compound, and the second charge transport layer may include a P-type charge transport compound.

Specifically, the N-type charge transport compound constituting the first charge transport layer or the second charge transport layer may be included as an organic polymer compound or an inorganic metal oxide.

More specifically, for example, the organic polymer compound may contain poly[(9,9-bis(3′-(N,N-dimethylamino)propyl)-2,7-fluorene)-alt-2,7-(9,9-dioctylfluorene)] or an organic PFN compound. Alternatively, the inorganic metal oxide may be one or more selected from the group consisting of zinc oxide and titanium oxide.

Alternatively, the inorganic metal oxide may be a component in which a precursor of the inorganic metal oxide is transferred to a metal oxide. Specifically, the inorganic metal oxide may be one or more selected from the group consisting of zinc oxide and titanium oxide.

For example, the P-type charge transport compound constituting the first charge transport layer or the second charge transport layer may contain an organic polymer compound or an inorganic metal oxide. More specifically, for example, the organic polymer compound may include poly(3,4-ethylene dioxythiophene)-poly(4-styrenesulfonate) or an organic PEDOT:PSS compound. Alternatively, the inorganic metal oxide may be one or more selected from the group consisting of zinc oxide and titanium oxide.

The organic solar cell according to the present invention may include an electrode containing one or more selected from aluminum (Al), indium tin oxide (ITO), fluorine doped tin oxide (FTO), Al doped zinc oxide (AZO), indium zinc oxide (IZO), indium zinc tin oxide (IZTO), zinc oxide-gallium oxide (ZnO-Ga₂O₃), zinc oxide-aluminum oxide (ZnO-Al₂O₃), antimony tin oxide (ATO), Al, Ag, and gold (Au). Specifically, the organic solar cell may include a first electrode and a second electrode, the first electrode may be Al, ITO, FTO, AZO, IZO, IZTO, ZnO—Ga₂O₃, ZnO—Al₂O₃, or ATO, and the second electrode may be Al, Ag, or Au.

In addition, the present invention provides a method of manufacturing an organic solar cell, which includes mixing a metal oxide precursor with a solvent to prepare a solution for a photostable charge transport layer and applying the solution for a photostable charge transport layer onto one surface or two surfaces of a photoactive layer to form a photostable charge transport layer.

In accordance with the method of manufacturing an organic solar cell according to the present invention, the organic solar cell is manufactured in which a first electrode, a first charge transport layer, a photoactive layer, a second charge transport layer, and a second electrode may be sequentially formed and stacked on a transparent substrate, and the photostable charge transport layer may be formed on one surface or two surfaces of the photoactive layer. Specifically, the solution for a photostable charge transport layer may be applied to a stacked structure in which the first electrode formed on the transparent substrate and the first charge transport layer are stacked, thereby forming the photostable charge transport layer. Alternatively, the solution for a photostable charge transport layer may be applied to a stacked structure in which the first electrode, the first charge transport layer, and the photoactive layer are formed and stacked on the transparent substrate, thereby forming the photostable charge transport layer.

Specifically, the preparing of the solution for a photostable charge transport layer may be performed by mixing a metal oxide precursor with a solvent at a concentration of 1 to 10 mg/ml. Specifically, the solution for a photostable charge transport layer may be prepared by mixing the metal oxide precursor with the solvent at a concentration of 1 to 10 mg/ml, 1 to 8 mg/ml, 1 to 6 mg/ml, 1 to 4 mg/ml, 2 to 10 mg/ml, 2 to 8 mg/ml, 2 to 6 mg/ml, 2 to 4 mg/ml, 5 to 10 mg/ml, 5 to 9 mg/ml, 5 to 8 mg/ml, 5 to 6 mg/ml, or 3 to 5 mg/ml.

The solvent may be one or more selected from the group consisting of deionized water, methanol, ethanol, propanol, butanol, pentanol, hexanol, methoxyethanol, ethoxyethanol, and 2-propanol (isopropyl alcohol).

The metal oxide precursor may be one or more selected from the group consisting of a tungsten powder, tungsten alkoxide, a tungsten carbonyl complex, tungsten ethoxide (tungsten(V,VI) ethoxide), halogenated tungsten, tungsten hydroxide, a molybdenum powder, molybdenum alkoxide, a molybdenum carbonyl complex, molybdenum sulfide, ammonium heptamolybdate tetrahydrate, a cobalt powder, cobalt alkoxide, a cobalt carbonyl complex, cobalt halide, cobalt acetate, a copper powder, copper alkoxide, a copper carbonyl complex, halogenated copper, copper nitrate, copper hydroxide, copper carbonate, a nickel powder, nickel alkoxide, a nickel carbonyl complex, halogenated nickel, nickel sulfide, and nickel hydroxide. Specifically, the metal oxide precursor may be a tungsten powder, tungsten alkoxide, a tungsten carbonyl complex, tungsten ethoxide, tungsten halide, tungsten hydroxide, a molybdenum powder, molybdenum alkoxide, a molybdenum carbonyl complex, molybdenum sulfide, or ammonium heptamolybdate tetrahydrate.

As an example, the forming of the photostable charge transport layer may be performed by applying the solution for a photostable charge transport layer onto one surface or two surfaces of the photoactive layer using a spin-coating method or a slot-die coating method. Specifically, the forming of the photostable charge transport layer may be performed by spin coating with the solution for a photostable charge transport layer at a speed of 1000 rpm to 4000 rpm. Alternatively, the forming of the photostable charge transport layer may be performed by slot-die coating with the solution for a photostable charge transport layer at a discharge amount of 0.1 to 1.0 ml/min and a speed of 0.1 to 1.0 m/min.

In addition, the forming of the photostable charge transport layer may further include performing heat treatment at a temperature ranging from 80° C. to 200° C. before and after the forming of the photostable charge transport layer. Specifically, a base material may be heat-treated at a temperature ranging from 80° C. to 150° C. for five minutes to twenty minutes before the forming of the photostable charge transport layer. Through the heat treatment of the solution containing a precursor of the photostable charge transport layer, there is an effect of aiding formation of a uniform thin film and improvement crystallinity in a subsequent process. In addition, after the forming of the photostable charge transport layer, the photostable charge transport layer may be heat-treated at a temperature ranging from 100° C. to 150° C. for five minutes to twenty minutes in the atmosphere. In this case, a metal oxide may be formed from the metal oxide precursor through the heat treatment.

As one example, the first charge transport layer may be manufactured of an N-type charge transport organic/inorganic compound, and the second charge transport layer may be manufactured of a P-type charge transport organic/inorganic compound. Alternatively, the first charge transport layer may be manufactured of an N-type charge transport compound, and the second charge transport layer may be manufactured of a P-type charge transport compound.

Specifically, the N-type charge transport compound constituting the first charge transport layer or the second charge transport layer may be manufactured of an organic polymer compound or an inorganic metal oxide.

More specifically, for example, the organic polymer compound may contain poly[(9,9-bis(3′-(N,N-dimethylamino)propyl)-2,7-fluorene)-alt-2,7-(9,9-dioctylfluorene)] or an organic PFN compound.

In addition, for example, the inorganic metal oxide may include an inorganic metal oxide precursor including one or more selected from the group consisting of zinc acetate and titanium (IV) isopropoxide.

Alternatively, the inorganic metal oxide may be a component in which a precursor of the inorganic metal oxide is transferred to a metal oxide. Specifically, the inorganic metal oxide may be one or more selected from the group consisting of zinc oxide and titanium oxide.

For example, the P-type charge transport compound constituting the first charge transport layer or the second charge transport layer may contain an organic polymer compound or an inorganic metal oxide. More specifically, for example, the organic polymer compound may include poly(3,4-ethylene dioxythiophene)-poly(4-styrenesulfonate) or an organic PEDOT:PSS compound.

Alternatively, for example, the inorganic metal oxide may include an inorganic metal oxide precursor including molybdenum diacetylacetonate dioxide, nickel(II) acetylacetonate, nickel(II) acetate, tungsten(V,VI) ethoxide, phosphomolybdic acid, phosphotungstic acid, and ammonium heptamolybdate tetrahydrate.

In addition, the photoactive layer may include one or more selected from the group consisting of phenyl-C61-butyrate methyl ester (phenyl-C61-butyric acid methyl ester or methyl[6,6]-phenyl-c61-butyrate) (PC6d3M), phenyl-C₇₁-butyrate methyl ester (phenyl-C71-butyric acid methyl ester or methyl[7,7]-phenyl-C71-butyrate) (PC₇₁BM), 3,9-bis(2-methylene-(3-(1,1-dicyanomethylene)-indaone))-5,5,11,11-tetrakis(4-hexylphenyl)-dithieno[2,3-d:2′,3′-d′]-s-indaceno[1,2-b:5,6-b′]dithiophene (ITIC), 3,9-bis(2-methylene-(3-(1,1-dicyanomethylene)-indaone))-5,5,11,11-tetrakis(5-hexylthienyl)-dithieno[2,3-d:2′,3′-d′]-s-indaceno[1,2-b:5,6-b′]dithiophene (ITIC-Th), 2,7-bis(3-dicyanomethylene-2Z-methylene-indan-1-one)-4,4,9,9-tetrahexyl-4,9-dihydro-s-indaceno[1,2-b:5,6-b′]dithiophene (IDIC), and 3,9-bis(2-methylene-((3-(1,1-dicyanomethylene)-6,7-difluoro)-indaone))-5,5,11,11-tetrakis(4-hexylphenyl)-dithieno[2,3-d:2′,3′-d′]-s-indaceno[1,2-b:5,6-b′]dithiophene (ITIC-4F) as an electron acceptor. Specifically, the photoactive layer may be phenyl-C₆₁-butyrate methyl ester (phenyl-C61-butyric acid methyl ester or methyl[6,6]-phenyl-c61-butyrate) (PC₆₁M), phenyl-C₇₁-butyrate methyl ester (phenyl-C71-butyric acid methyl ester or methyl[7,7]-phenyl-C71-butyrate) (PC₇₁BM), 3,9-bis(2-methylene-(3-(1,1-dicyanomethylene)-indaone))-5,5,11,11-tetraki s(4-hexylphenyl)-dithieno[2,3-d:2′,3′-d′]-s-indaceno[1,2-b:5,6-b′]dithiophene (ITIC), 3,9-bis(2-methylene-(3-(1,1-dicyanomethylene)-indaone))-5,5,11,11-tetrakis(5-hexylthienyl)-dithieno[2,3-d:2′,3′-d′]-s-indaceno[1,2-b:5,6-b′]dithiophene (ITIC-Th), 2,7-bis(3-dicyanomethylene-2Z-methylene-indan-1-one)-4,4,9,9-tetrahexyl-4,9-dihydro-s-indaceno[1,2-b:5,6-b′]dithiophene (IDIC), or 3,9-bis(2-methylene-((3-(1,1-dicyanomethylene)-6,7-difluoro)-indaone))-5, 5,11,11-tetraki s(4-hexylphenyl)-dithieno[2,3-d:2′,3′-d′]-s-indaceno[1,2-b:5,6-b]dithiophene (ITIC-4F).

As an example, the method of manufacturing an organic solar cell according to the present invention may further include forming the first electrode. Specifically, the first electrode may be formed using a physical vapor deposition (PVD) method, a chemical vapor deposition (CVD) method, an atomic layer deposition (ALD) method, or a thermal vapor deposition method. In addition, the method of manufacturing an organic solar cell according to the present invention may further include forming the second electrode on the second charge transport layer. Specifically, the second electrode is deposited in a thermal evaporator exhibiting a vacuum degree of 5×10⁻⁷ Torr or less, Al, Ag, or Au may be used as a usable material, and the usable material may be selected in consideration of a structure of a solar cell to be manufactured.

Hereinafter, the present invention will be described in more detail with reference to examples and drawings on the basis of the above description. The following examples are for illustrative purposes, and the scope of the present invention is not limited thereto.

### EXAMPLE 1

In order to manufacture an inverted structure organic solar cell to which a charge transport layer and a photostable charge transport layer are applied, thicknesses and manufacturing processes of the transparent substrate 110, the first electrode 120, the electron transport layer 130, the photoactive layer 140, the photostable charge transport layer 150-1, the hole transport layer 150, and the second electrode 160 were optimized.

Specifically, the inverted structure organic solar cell was manufactured in a structure of ITO glass (180 nm)/electron transport layer (ZnO and 30 nm)/SMD2:ITIC-Th=1:1.25 (100 nm)/photostable charge transport layer (30 nm)/hole transport layer (PEDOT:PSS) (HTL Solar and 30 nm)/Ag (100 nm). More details will be described in operations 1.1 to 1.7 below.

1.1. Preparation of Solution for Hole Transport Layer

In order to prepare a solution for the hole transport layer 150, 5 ml vial was prepared by vacuum and nitrogen substitution. In order to use HTL Solar (Clevios 388) purchased from Heraeus Holding as a hole transport layer in the inverted structure organic solar cell, a solution was filtered using 5 μm nylon filter. After the filtration, a black transparent solution was obtained. Thereafter, the solution was stirred in a roll-mixer and stored at room temperature.

1.2. Preparation of Solution for Photostable Charge Transport Layer

In order to prepare a solution for the photostable charge transport layer 150-1, 5 ml vial was prepared by vacuum and nitrogen substitution. Hexavalent tungsten ethoxide (tungsten (VI) ethoxide, CAS:62571-53-3) purchased from Alfa aesar at a concentration of 1 to 10 mg/ml was put into 1-hexanol (a 98% reagent grade, CAS:111-27-3) to 2-propanol(isopropyl alcohol, 99.5% anhydrous, CAS: 67-63-0) and stirred at room temperature. In this case, the vial was sealed with a para-film and a Teflon-film to obtain a solution in which white particles float. After stirring for one hour, a sonicator was filled with deionized water, the deionized water was fixed to reach a 2/3 position of the vial and then ultrasonic-treated for thirty minutes to obtain a white turbid solution. Thereafter, the solution was stirred and stored in a roll-mixer at room temperature.

1.3. Manufacturing of Organic Solar Cell (1): Preparation and Pretreatment

ITO glass was used as the transparent substrate 110 and the electrode 120. The patterned ITO glass was cleaned through ultrasonic treatment in the sonicator in the order of acetone, neutral detergent (Alconox), isopropyl alcohol (IPA), and deionized water. After the ultrasonic treatment was performed in each operation, the patterned ITO glass was rinsed with deionized water, and the deionized water was removed with nitrogen (N₂) gas. After the last ultrasonic treatment in the deionized water was completed, the ITO glass was heated and dried on a hotplate at a temperature of 120° C. for ten minutes. A surface of the dried ITO glass was modified to be hydrophilic through UV-ozone (UVO) treatment in a UVO-cleaner device.

1.4. Manufacturing of Organic Solar Cell (2): Coating of Electron Transport Layer and Photoactive Layer

A ZnO precursor, which was the electron transport layer 130 formed by a sol-gel method, was diluted in 2-methoxyethanol (99.8%, CAS:109-86-4) at a ratio of 1:1 to 1:5, and spin-coating was performed on the hydrophilically modified ITO glass, which was the electrode 120, with the diluted ZnO precursor to a thickness ranging from 30 nm to 40 nm in the ambient atmosphere. The coated ITO glass was heated and sintered on a hot plate at a temperature ranging from 150° C. to 200° C. for one hour.

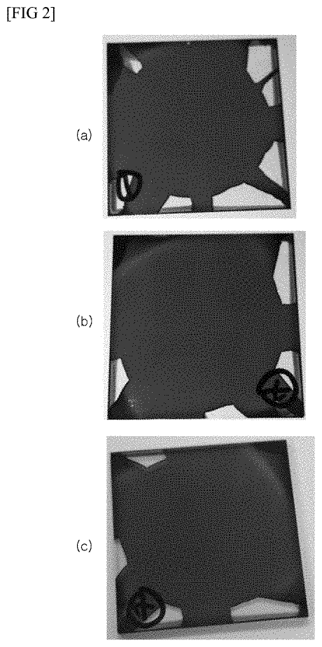

A solution for a photoactive layer was prepared so as to apply the photoactive layer 140. In this case, the used photoactive layer was formed in a bulk heterojunction structure in which an SMD2 copolymer which was an MBDD-T-based copolymer served as an organic donor and an ITIC-Th (CAS:1899344-13-1) served as an organic acceptor and prepared at a weight ratio concentration of 0.5 to 0.7 in chlorobenzene containing 0.5 to 1.0 volume ratio of 1,8-diiodooctane. The solution formed before the coating underwent an activation process at a temperature of 90° C. in the ambient atmosphere. Then, spin coating was performed with the solution to a thickness ranging from 80 nm to 100 nm in a glove box. The formed photoactive layer was heat-treated on a hot plate at a temperature ranging from 100° C. to 160° C. for fifteen minutes (see FIG. 2A).

1.5. Manufacturing of Organic Solar Cell (3): Coating of Photostable Charge Transport Layer and Hole Transport Layer

After the formation of the photoactive layer, the photoactive layer was spin-coated with the solution for the photostable charge transport layer 150-1, which was prepared in operation 1.2, to a thickness ranging from 30 nm to 40 nm in the atmosphere. In this case, the solution for the photostable charge transport layer should be applied onto an entire surface, and immediately spin coating was performed without a time difference. When visually observed, it was observed that a color was changed to an emerald color, a green color, a bright yellow color, and a transparent state while the photostable charge transport layer was applied. In this case, when the coating is interrupted in a state in which the color change occurs during spin coating, a rough and thin film is formed. The spin coating was carried out until there was no more color change. Thereafter, a clean and thin film in a transparent state was capable of being obtained. Then, the formed photostable charge transport layer was heat-treated on a hot plate at a temperature ranging from 80° C. to 150° C. for ten minutes in the atmosphere (see FIG. 2B).

After the heat treatment of the photostable charge transport layer, spin coating was performed with the HTL Solar solution, which is the solution for the hole transport layer 150 prepared in operation 1.1, to a thickness ranging from 30 nm to 40 nm in the ambient atmosphere. In this case, the solution for the hole transport layer should be applied onto an entire surface, and immediately spin coating was performed without a time difference. When visually observed, it was observed that the hole transport layer was applied and a thin film form was collected in a circular shape to a central portion. The spin coating was performed for about 30 seconds until the form collected in a circle completely disappeared. Thereafter, a dark blue clean and thin film was formed (see FIG. 2C).

1.6: Manufacturing of Organic Solar Cell (4): Formation of Electrode

In order to form the upper electrode 160 on the hole transport layer, an organic solar cell was transferred to a high vacuum deposition chamber (less than 10⁻⁶ Torr) using a cryo-pump. Ag in a state of a pallet was thermally deposited with a thickness of 100 nm at a rate of 2.5 A/s. A photoactive area of the manufactured device ranged from 0.04 cm² to 0.12 cm².

### EXAMPLE 2

An organic solar cell was manufactured in the same manner as in Example 1, except that a photostable charge transport layer was formed between an electron transport layer and a photoactive layer when the organic solar cell was manufactured.

### EXAMPLE 3

An organic solar cell was manufactured in the same manner as in Example 1, except that photostable charge transport layers were each formed between an electron transport layer and a photoactive layer and between the photoactive layer and a hole transport layer when the organic solar cell was manufactured.

### EXAMPLE 4

An organic solar cell was manufactured in the same manner and the same condition as in Example 1. A bulk heterojunction structure was formed of a material used when the photoactive layer 140 was formed using a P(Cl)-based copolymer as an organic donor and an ITIC-Th as an organic acceptor at a ratio ranging from 1:1 to 1:1.2, and a solution was prepared at a 0.7 to 1.2 weight ratio concentration in chlorobenzene containing 1,8-diiodooctane at a 0.5 to1.0 volume ratio. The solution formed before the coating underwent an activation process at a temperature of 90° C. in the atmosphere. Then, spin coating was performed with the solution to a thickness ranging from 80 nm to 100 nm in a glove box. A formed photoactive layer was heat-treated on a hot plate at a temperature ranging from 100° C. to 140° C. for ten minutes.

### EXAMPLE 5

An organic solar cell was manufactured in the same manner as in Example 4, except that a photostable charge transport layer was formed between an electron transport layer and a photoactive layer when the organic solar cell was manufactured.

### EXAMPLE 6

An organic solar cell was manufactured in the same manner as in Example 4, except that photostable charge transport layers were each formed between an electron transport layer and a photoactive layer and between the photoactive layer and a hole transport layer when the organic solar cell was manufactured.

### EXAMPLE 7

In order to manufacture a non-inverted structure organic solar module to which a charge transport layer and a photostable charge transport layer are applied, thicknesses and manufacturing processes of a transparent substrate 110, a first electrode 120, an electron transport layer 130, a photoactive layer 140, a photostable charge transport layer 150-1, a hole transport layer 150, and a second electrode 160 were optimized.

Specifically, the inverted structure organic solar module was manufactured in a structure of ITO film (180 nm)/electron transport layer (ZnO and 30 nm)/SMD2:ITIC=1:1 (100 nm)/ultraviolet light absorption photostable charge transport layer (30 nm)/hole transport layer) (HTL Solar and 20 nm)/Ag (10 μm). Unlike the unit cell, a module may be manufactured using both ITO glass and the ITO film. More details will be described in operations 7.1 to 7.7 below.

7.1. Preparation of Solution for Hole Transport Layer

In order to prepare a solution for the hole transport layer 150, 60 ml vial was prepared, and the same solution as in operation 1.1 of Example 1 was used. In addition, a solution is obtained using the same filter and stirred in a roll-mixer and stored at room temperature.

7.2. Preparation of Solution for Photostable Charge Transport Layer

In order to prepare a solution for the hole transport layer 150-1, 60 ml vial was prepared by vacuum and nitrogen substitution to prepare the same solution as in operation 1.2 of Example 1. In addition, the same sealing method and the same ultrasonic treatment were performed to obtain a white turbid solution that is stirred in a roll-mixer and stored at room temperature.

7.3: Manufacturing of Organic Solar Module (1): Preparation and Pretreatment

An ITO film was used as the transparent substrate 110 and the electrode 120. After the patterned ITO film underwent the same pretreatment as in operation 1.3 of Example 1, a surface of the patterned ITO film was modified to be hydrophilic through UV-ozone treatment in a UVO-cleaner device.

7.4. Manufacturing of Organic Solar Module (2): Coating of Electron Transport Layer and Photoactive Layer

The hydrophilic modified ITO film, which was the electrode 120, was slot-die-coated with ZnO nanoparticles, which were the electron transport layer 130, to a thickness ranging from 30 nm to 40 nm in the atmosphere. After the coating, the coated film was heat-treated through a hot air blower at a temperature ranging from 80° C. to 120° C.

A solution for a photoactive layer was prepared so as to apply the photoactive layer 140. In this case, the used photoactive layer was formed in a bulk heterojunction structure in which an SMD2 which was an MBDD-T-based copolymer served as an organic donor and an ITIC-Th served as an organic acceptor, and a solution was prepared at a weight ratio concentration of 0.5 to 0.7 in chlorobenzene containing 0.5 to 1.0 volume ratio of 1,8-diiodooctane. The solution formed before the coating underwent an activation process at a temperature of 90° C. in the atmosphere. Thereafter, slot-die coating was performed with the solution to a thickness ranging from 80 nm to 100 nm in the atmosphere. After the coating, the formed photoactive layer was heat-treated through a hot air blower at a temperature ranging from 80° C. to 120° C.

7.5. Manufacturing of Organic Solar Module (3): Coating of Photostable Charge Transport Layer and Hole Transport Layer

After the formation of the photoactive layer 140, the photoactive layer was slot-die-coated with the solution for the photostable charge transport layer 150-1, which was prepared in operation 7.2, to a thickness ranging from 30 nm to 40 nm in the ambient atmosphere. In this case, after the coating, the formed photostable charge transport layer was heat-treated through a hot air blower at a temperature ranging from 80° C. to 120° C.

After the heat treatment of the photostable charge transport layer, slot-die coating was performed with the solution for the hole transport layer 150 prepared in operation 7.1 to a thickness ranging from 200 nm to 1 μm in the ambient atmosphere. In this case, after the coating, the formed hole transport layer was heat-treated through a hot air blower at a temperature ranging from 80° C. to 120° C.

7.6. Manufacturing of Organic Solar Module (4): Formation of Electrode

In order to form the upper electrode 160 on the hole transport layer, an Ag paste was applied through screen printing with a thickness ranging from 100 nm to 10 μm in the ambient atmosphere. After the coating, in order to cure an Ag electrode, a UV light curing machine was used to form the Ag electrode. A photoactive area of the manufactured module ranged from 10 cm² to 100 cm².

### EXAMPLE 8

An organic solar cell was manufactured in the same manner and the same condition as in Example 1. A bulk heterojunction structure was formed of a material used when the photoactive layer 140 was formed using a P(Cl—Cl)-based copolymer as an organic donor and an ITIC-4F as an organic acceptor at a ratio ranging from 1:1 to 1:1.6, and a solution was prepared at a 0.7 to 1.2 weight ratio concentration in xylene containing 1-phenylnaphthalene at a 0.5 to1.0 volume ratio.

The solution formed before the coating underwent an activation process at a temperature of 90° C. in the ambient atmosphere. Then, spin coating was performed with the solution to a thickness ranging from 80 nm to 100 nm in a glove box. The formed photoactive layer was heat-treated on a hot plate at a temperature ranging from 100° C. to 160° C. for ten minutes.

### EXAMPLE 9

An organic solar module was manufactured through the same method and the same condition as in Example 8. In order to form a photostable charge transport layer suitable for a photoactive layer with a high HOMO level (an HOMO level having a lower energy level), in preparation of a solution for the photostable charge transport layer solution, ammonium heptamolybdate tetrahydrate (CAS:12054-85-2) was put into 2-propanol (isopropyl alcohol, 99.5% anhydrous, CAS:67-63-0) at a concentration ranging from of 1 mg/ml to 10 mg/ml and stirred at room temperature to form the photostable charge transport layer, thereby manufacturing the organic solar module.

### COMPARATIVE EXAMPLE 1

An organic solar cell was manufactured in the same manner as in Example 1, except that a photostable charge transport layer was not formed.

### COMPARATIVE EXAMPLE 2

An organic solar cell was manufactured in the same manner as in Example 1, except that a photostable charge transport layer was formed between a hole transport layer and a second electrode.

### COMPARATIVE EXAMPLE 3

An organic solar cell was manufactured in the same manner as in Example 1, except that a photostable charge transport layer was formed between an electron transport layer and a first electrode.

### COMPARATIVE EXAMPLE 4

An organic solar cell was manufactured in the same manner as in Example 4, except that a photostable charge transport layer was not formed.

### COMPARATIVE EXAMPLE 5

An organic solar cell was manufactured in the same manner as in Example 4, except that a photostable charge transport layer was formed between a hole transport layer and a second electrode.

### COMPARATIVE EXAMPLE 6

An organic solar cell was manufactured in the same manner as in Example 1, except that a photostable charge transport layer was formed between an electron transport layer and a first electrode.

### COMPARATIVE EXAMPLE 7

An organic solar cell was manufactured in the same manner as in Example 7, except that a photostable charge transport layer was not formed.

### COMPARATIVE EXAMPLE 8

An organic solar cell was manufactured in the same manner as in Example 8, except that a photostable charge transport layer was not formed.

### EXPERIMENTAL EXAMPLE 1

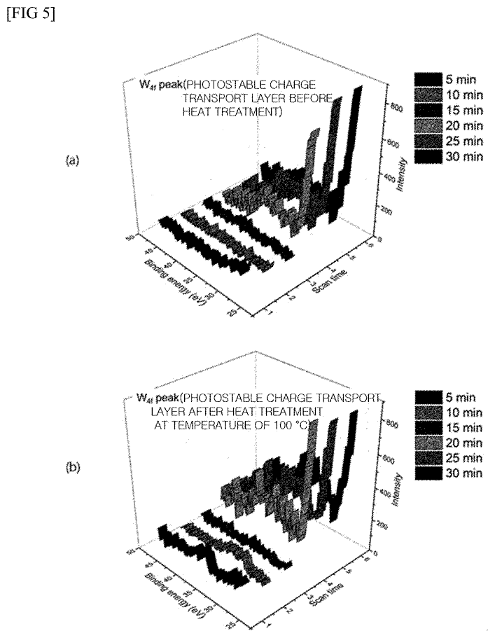

In order to confirm a chemical characteristic and a surface characteristic of the photostable charge transport layer of the organic solar cell according to the present invention, the photostable charge transport layer and the hole transport layer, which were manufactured in Example 1, were analyzed using X-ray photoelectron spectroscopy (XPS) and an atomic force microscope (AFM), and the results were shown in FIGS. 5 to 7.

Specifically, XPS depth profiling of the photostable charge transport layer and the hole transport layer was analyzed using XPS (ULVAC-PHI 5000 VersaProbe, Phi(1)).

In addition, XPS analysis and AFM measurement were performed in the same manner as in Example 1 using a sample in which spin coating was performed with the photostable charge transport layer and the hole transport layer to be sequentially formed on the ITO glass substrate. The XPS analysis was performed such that a sputtering was performed from a surface of the sample (the hole transport layer) to a bottom of the sample (the photostable charge transport layer) for five minutes each, and an inner crystal structure and a binding state of a film were analyzed through X-ray scanning five to ten times.

XPS depth profiling analysis was performed on the metal oxide according to the present invention to confirm that the tungsten ethoxide used as the precursor was transferred to the form of tungsten oxide through heat treatment, and the results were shown in FIG. 5. FIG. 5A shows a result of the XPS analysis of the photostable charge transport layer before heat treatment, and FIG. 5B shows a result of the XPS analysis of the photostable charge transport layer after heat treatment at a temperature of 100° C. Generally, a W4f peak in a state of a metal precursor was observed in the range of 30 eV to 34 eV, and a W4f peak in a state of tungsten oxide was observed in the range of 36 eV to 40 eV. On the basis of the results of the XPS analysis before and after the heat treatment, it was shown that the peaks exhibited wide in the range of 30 eV to 34 eV before the heat treatment were exhibited strong at 40 eV after the heat treatment. Consequently, it was confirmed that the peaks measured in the range of 30 eV to 34 eV before the heat treatment were measured in the vicinity of 40 eV after the heat treatment, and thus the photostable charge transport layer was transferred to tungsten oxide through a heat treatment process.

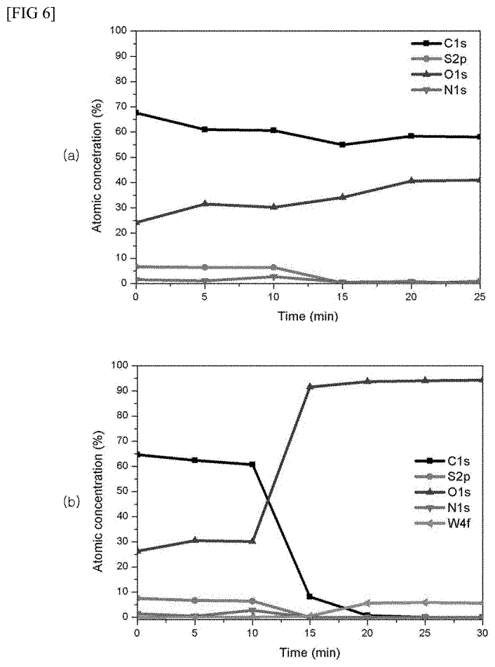

Referring to FIG. 6A, in a sample in which only the hole transport layer was introduced, element signals of C1s, S2p, Ols, and N1s, which were characteristic structures of an HTL Solar which was the hole transport layer, were measured. Referring to FIG. 6B, in a sample in which both the photostable charge transport layer and the hole transport layer were introduced, the element signals of C1s, S2p, O1s, and N1s, which were characteristic structures of the hole transport layer atop the photostable charge transport layer, were measured, and then the element signals of W4f and O1s due to the photostable charge transport layer tended to be increased. This means that a WO₃ layer which is the photostable charge transport layer may effectively block UV between the photoactive layer and the hole transport layer.

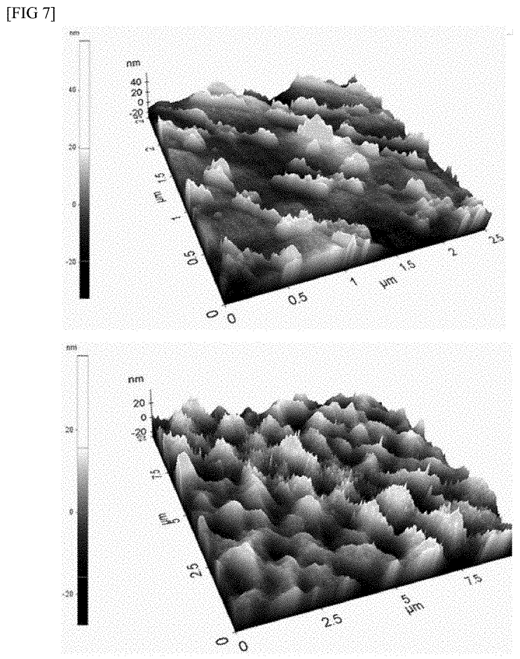

Referring to FIG. 7, in the sample in which only the hole transport layer was introduced (the upper photograph), surface roughness (surface morphology) was formed to be larger to exhibit an agglomeration phenomenon and root mean square (RMS) roughness of 8.711 nm, and this means that a rough and thin film was formed. In addition, the sample in which both the photostable charge transport layer and the hole transport layer were introduced (the lower photograph) exhibited a relatively uniform thin film phenomenon and RMS roughness of 4.117 nm. Consequently, when compared with a case in which the hole transport layer was introduced as a single layer, in a case in which the photostable charge transport layer was introduced as a dual layer, a more uniform surface state of the thin film was exhibited and thus a characteristic advantageous for charge transfer was exhibited.

### EXPERIMENTAL EXAMPLE 2

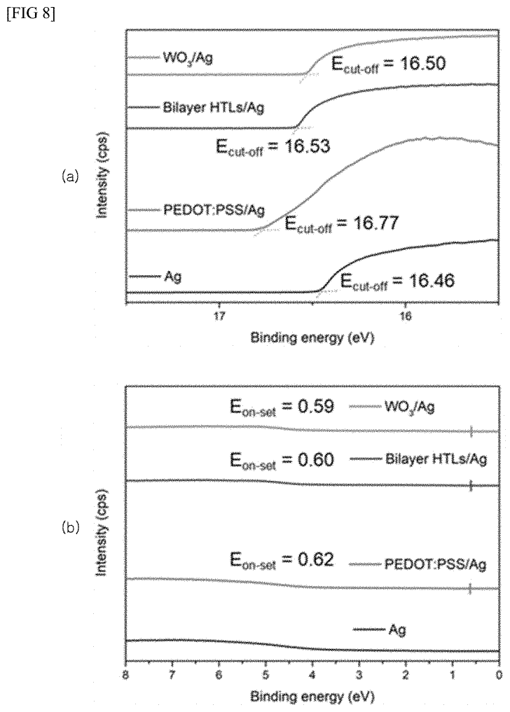

In order to confirm an electrical characteristic and an optical characteristic of the organic solar cell according to the present invention, UV photoelectron spectroscopy (UPS), finite-difference time domain (FDTD) analysis, and UV-visible (Vis) spectroscopy analysis were performed on Example 1, Example 7, and Example 8, and the results were shown in FIGS. 8 to 13.

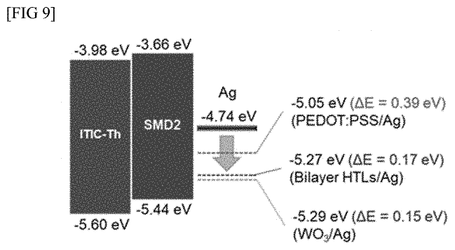

The UPS is to analyze electrical characteristic of the photoactive layer, photostable charge transport layer, the hole transport layer, and Ag which is an electrode. A sample formed by spin coating on an ITO transparent electrode in the same processes of the preparing of the solutions of the photoactive layer, the photostable charge transport layer, and hole transport layer in Example 1 was used. Referring to FIGS. 8 and 9, a hole injection barrier energy between the SMD2 donor and the Ag electrode, which constitute the photoactive layer, was measured as 0.70 eV. In addition, when the HTL Solar (PEDOT:PSS) which was the hole transport layer was introduced, the hole injection barrier energy was reduced to 0.39 eV, and when the dual layer structure (bilayer HTLs) including the photostable charge transport layers, the hole injection barrier exhibited a lower 0.17 eV.

In addition, in the FDTD analysis, a structure of an organic solar cell identical to the structure of Example 1 was set in an imaginary space, and in order for an optical characteristic simulation for optical stability evaluation of the organic solar cell, a Ag paste was applied to a thickness ranging from 100 nm to 10 p.m through screen printing, an electrode was formed using a UV light curing machine, and then light corresponding to a wavelength band and an intensity of a light source, which are identical to those of sunlight, was irradiated in the same direction to perform the optical characteristic simulation.

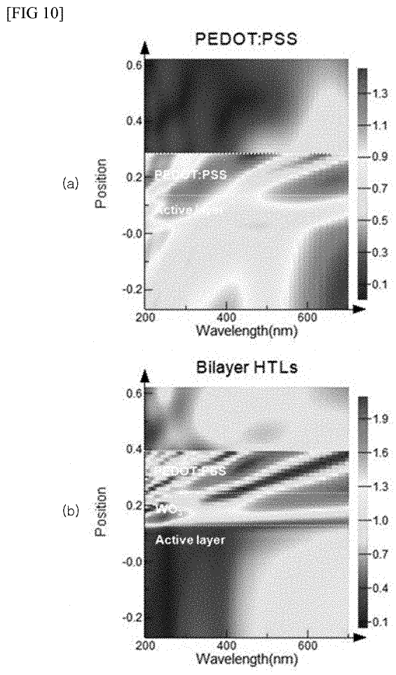

Referring to FIG. 10, in the structure in which only the HTL Solar (PEDOT:PSS) which was the hole transport layer was introduced, pieces of light in a short wavelength band (λ=200 nm to 400 nm) and a long wavelength band (λ=400 nm to 700 nm) passed through the photoactive layer, whereas in the structure (bilayer HTLs) in which both the photostable charge transport layer and the hole transport layer were introduced, the pieces of light in the short wavelength band hardly passed through the photoactive layer, and thus the results exhibited that only the pieces of light in the long wavelength band passed through the photoactive layer. Consequently, it was confirmed that, when both the photostable charge transport layer and the hole transport layer were introduced to form the dual layer, photostability of the photoactive layer may be effectively improved.

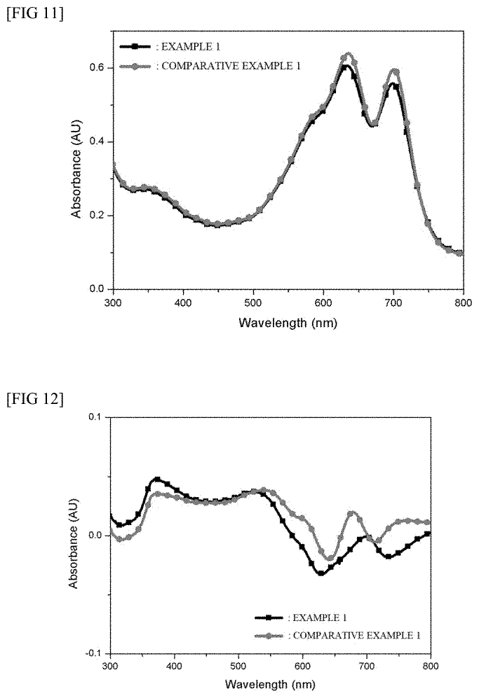

The UV-Vis spectroscopy analysis was performed using a sample in which the photoactive layer, the photostable charge transport layer, and the hole transport layer were manufactured through spin coating in the same manner as in Example 1 and Comparative Example 1. FIG. 1B is a schematic image illustrating a structure of the sample manufactured in the same manner as in Example 1, and FIG. 11 is a graph showing measured results of absorbance of the photoactive layer/the photostable charge transport layer/the hole transport layer using a glass substrate as a blank. Referring to FIG. 11, the sample in which the photostable charge transport layer was introduced exhibited lower absorbance.

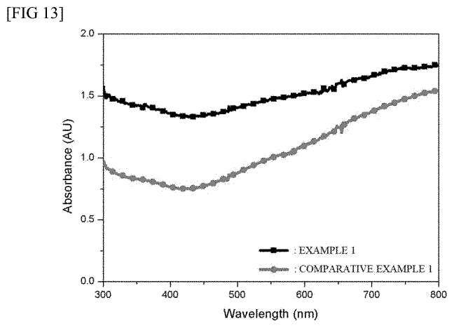

FIGS. 12 and 13 are graphs showing measured results of absorbance of the photostable charge transport layer/the hole transport layer using the photoactive layer as a blank in the samples manufactured in the same manner as in Example 1 and Comparative Example 1. FIG. 12 is a graph showing the result of absorbance measured in the forward direction (toward the photostable charge transport layer), and FIG. 13 is a graph showing the result of absorbance measured in the backward direction (toward the hole transport layer). Referring to FIGS. 12 and 13, in both directions, the sample in which the photostable charge transport layer was introduced exhibited higher absorbance in a short wavelength region (λ=300 nm to 450 nm). This means that light in the short wavelength region incident on the photoactive layer may be effectively reduced in the photostable charge transport layer.

### EXPERIMENTAL EXAMPLE 3

In order to confirm the characteristics of the organic solar cell according to the present invention, the organic solar cells manufactured in Examples 1 to 9 and Comparative Examples 1 to 8 were analyzed using a solar simulator (Newport Oriel, 100 mWcm⁻²), and the results were shown in Tables 1 and 2 below.

Specifically, the solar simulator was characterized with an air mass (AM) 1.5G filter. An intensity of the solar simulator was set to 100 mWcm⁻² using a silicon reference device certified by national institute of advanced industrial science and technology (AIST). A current-voltage behavior was measured using a Keithley 2400 SMU. An external quantum efficiency (EQE) behavior was measured using a Polaronix K3100 IPCE measurement system (McScience Inc.). In addition, a fill factor (FF) was calculated using voltage value (Vₘₐₓ)×current density (Jₘₐₓ)/(VOC×J_{SC}) at a maximum power point, and energy conversion efficiency was calculated using FF×J_{SC}×V_{OC}/Pᵢₙ and Pᵢₙ=100 mWcm⁻².

TABLE 1

| | Charge transport layer | | | |
|---|---|---|---|---|
| | V_{OC} [V] | J_{SC} [mAcm⁻²] | FF [%] | PCE [%] |
| Comparative | 0.696 | 16.6 | 62.0 | 7.2 |
| Example 1 | | | | |
| Example 1 | 0.858 | 16.2 | 63.3 | 8.8 |
| Comparative | 0.878 | 12.3 | 62.1 | 6.7 |
| Example 2 | | | | |
| Example 2 | 0.737 | 15.9 | 60.0 | 7.1 |
| Comparative | 0.757 | 16.0 | 60.2 | 7.2 |
| Example 3 | | | | |
| Example 3 | 0.798 | 17.7 | 51.8 | 7.3 |
| Comparative | 0.717 | 17.9 | 56.2 | 7.2 |
| Example 4 | | | | |
| Example 4 | 0.777 | 19.2 | 56.9 | 8.5 |
| Comparative | 0.737 | 17.7 | 58.6 | 7.7 |
| Example 5 | | | | |
| Example 5 | 0.757 | 17.8 | 58.3 | 7.8 |
| Comparative | 0.777 | 17.5 | 55.4 | 7.5 |
| Example 6 | | | | |
| Example 6 | 0.777 | 19.2 | 52.8 | 7.8 |
| Comparative | 7.91 | 1.09 | 44.22 | 3.83 |
| Example 7 | | | | |
| Example 7 | 8.48 | 1.04 | 49.72 | 4.38 |

Referring to Table 1, it can be seen that the characteristics of organic solar cells are improved according to the position of the photostable charge transport layer. Referring to Table 1, it was confirmed that the organic solar cells manufactured in Examples 1 to 3 were excellent in short-circuit current density of 15.9 mAcm⁻² or more, an open-circuit voltage of 0.767 V or more, and energy conversion efficiency of 7.1% or more. Referring to Table 1, it was confirmed that the organic solar cells manufactured in Examples 4 to 6 were excellent in short-circuit current density of 17.8 mAcm⁻² or more, an open-circuit voltage of 0.757 V or more, and energy conversion efficiency of 7.8% or more.

In addition, in the large-area organic solar modules manufactured in Example 7 and Comparative Example 7, after the use of the ultraviolet light curing machine used in the formation of the electrode, the solar module of the hole transport layer in the single layer structure of Comparative Example 7 exhibited energy conversion efficiency of 3.83%. Meanwhile, the large-area organic solar module of the dual layer structure including the photostable charge transport layer of Example 7 exhibited more excellent energy conversion efficiency of 4.38%. However, as a type of the donor polymer of the photoactive layer was changed, the energy conversion efficiency was slightly reduced when compared with Examples 1 and 4 even in the same structure.

Consequently, it can be seen that the organic solar cell according to the present invention has excellent organic solar cell performance by adjusting the position of the photostable charge transport layer. In addition, when the energy level of the donor polymer of the photoactive layer is varied, it can be seen that the performance may be differently exhibited according to the introduction of the hole transport layer and the photostable charge transport layer.

In addition, in order to compare the photostability characteristics of organic solar cells according to types of photostable charge transport layers, the characteristics of the organic solar cells manufactured in Examples 8 and 9 and Comparative Example 8 were shown in Table 2.

TABLE 2

| | Charge transport layer | | | |
|---|---|---|---|---|
| | V_{OC} [V] | J_{SC} [mAcm⁻²] | FF [%] | PCE [%] |
| Comparative | 0.777 | 18.9 | 66.0 | 9.7 |
| Example 8 | | | | |
| Example 8 | 0.858 | 18.5 | 66.3 | 10.6 |
| Example 9 | 0.858 | 19.0 | 65.6 | 10.7 |

Referring to Table 2, the same as when the photostable charge transport layer containing a tungsten oxide was used (Example 8), it can be seen that, when the photostable charge transport layer containing a molybdenum oxide was used (Example 9), performance was improved. Meanwhile, in Comparative Example 8, it can be seen that the solar cell performance was significantly different because the photostable charge transport layer was not formed. Consequently, even when the energy level of the of the photoactive layer is varied, it can be seen that the performance may be improved according to the introduction of the hole transport layer and the photostable charge transport layer.

### EXPERIMENTAL EXAMPLE 4

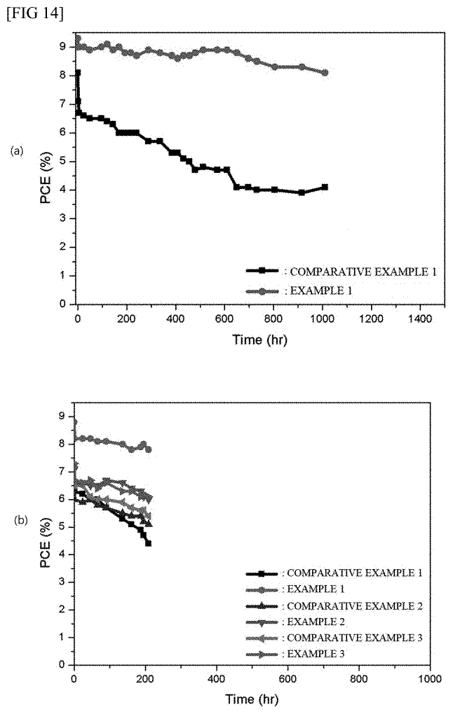

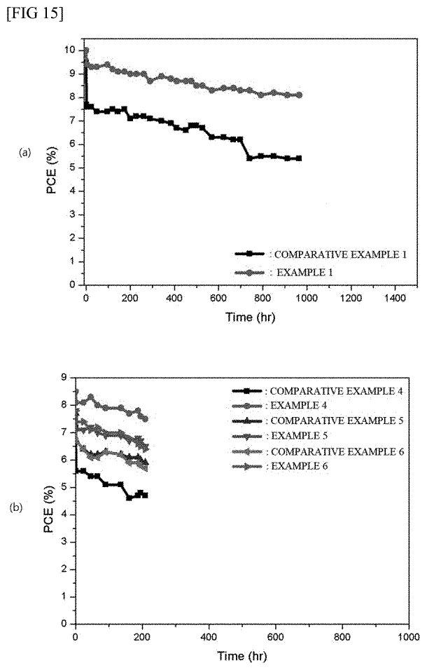

In order to evaluate photostability and long-term stability of the organic solar cells according to the present invention, the inverted-structure organic solar cells manufactured in Examples 1 to 9 and Comparative Examples 1 to 7 passed through a UV curing system (LICHTZEN Inc.), a quantity of light of 1100 mJcm⁻² was irradiated to the inverted-structure organic solar cells, and then photostability evaluation was performed. In addition, the inverted organic solar cells manufactured in Examples 1 to 9 and Comparative Examples 1 to 7 were stored at room temperature/humidity in the atmosphere without undergoing an encapsulation process, and performance and durability were continuously evaluated. In this case, in order to apply to a process of a commercialization stage such as a module manufacturing and a large-area device manufacturing, durability (long-term stability) was evaluated under the above process conditions and storage conditions, and the results were shown in Table 3 and FIGS. 14 and 15.

TABLE 3

| | Charge transport layer | | | | |
|---|---|---|---|---|---|
| | | | | | Reduction |
| | V_{OC} [V] | J_{SC} [mAcm⁻²] | FF [%] | PCE [%] | rate [%] |
| Comparative | 0.656 | 16.0 | 59.9 | 6.3 | 12.5 |
| Example 1 | | | | | |
| Example 1 | 0.858 | 15.8 | 60.2 | 8.2 | 6.81 |
| Comparative | 0.676 | 15.4 | 57.9 | 6.0 | 10.44 |
| Example 2 | | | | | |
| Example 2 | 0.717 | 15.6 | 59.2 | 6.6 | 7.04 |
| Comparative | 0.696 | 15.3 | 60.5 | 6.5 | 9.72 |
| Example 3 | | | | | |
| Example 3 | 0.757 | 16.8 | 52.6 | 6.7 | 8.21 |
| Comparative | 0.676 | 17.8 | 46.7 | 5.6 | 22.22 |
| Example 4 | | | | | |
| Example 4 | 0.757 | 18.6 | 57.4 | 8.1 | 4.70 |
| Comparative | 0.676 | 17.5 | 57.0 | 6.7 | 12.98 |
| Example 5 | | | | | |
| Example 5 | 0.717 | 17.7 | 56.1 | 7.1 | 8.97 |
| Comparative | 0.717 | 16.7 | 56.1 | 6.7 | 10.66 |
| Example 6 | | | | | |
| Example 6 | 0.757 | 18.3 | 53.4 | 7.4 | 5.12 |
| Comparative | 0.717 | 17.3 | 59.1 | 7.9 | 18.55 |
| Example 8 | | | | | |
| Example 8 | 0.818 | 17.6 | 63.4 | 9.1 | 14.15 |
| Example 9 | 0.858 | 17.6 | 64.3 | 9.7 | 9.34 |

<Test Result of Photostability>

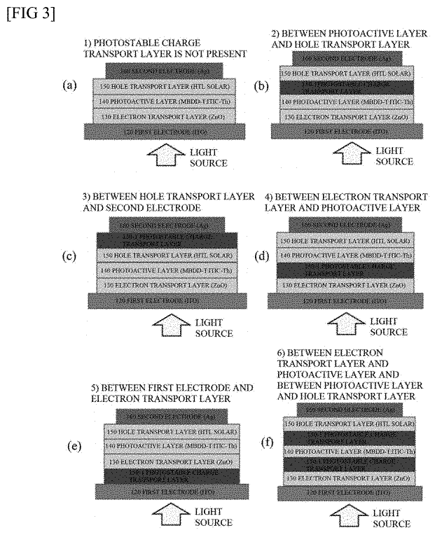

Referring to Table 3, the solar cell in which only the hole transport layer single layer of Comparative Example 1 was introduced (see FIG. 3A) exhibited the energy conversion efficiency of 6.3% and the efficiency reduction rate of 12.5%, and the solar cell in which the dual layer including the photostable charge transport layer of Example 1 between the photoactive layer and the hole transport layer was introduced exhibited the energy conversion efficiency of 8.8% and the efficiency reduction rate of 6.81%. In addition, the solar cell including the photostable charge transport layer of Example 2 between the electron transport layer and the photoactive layer (see FIG. 3D) exhibited the energy conversion efficiency of 6.6% and the efficiency reduction rate of 7.04%. In addition, the solar cell including the photostable charge transport layer of Example 3 between the electron transport layer and the photoactive layer and between the photoactive layer and the hole transport layer (see FIG. 3F) exhibited the energy conversion efficiency of 6.7% and the efficiency reduction rate of 8.21%. As described above, the result was obtained such that the photostability was significantly improved in the solar cell in which the photostable charge transport layer was introduced between the photoactive layer and the hole transport layer and between the photoactive layer and the electron transport layer. However, the organic solar cell in which the photostable charge transport layer was introduced at another position exhibited the efficiency reduction rate of 10% or more, and thus the result in which photostability was lowered was obtained.

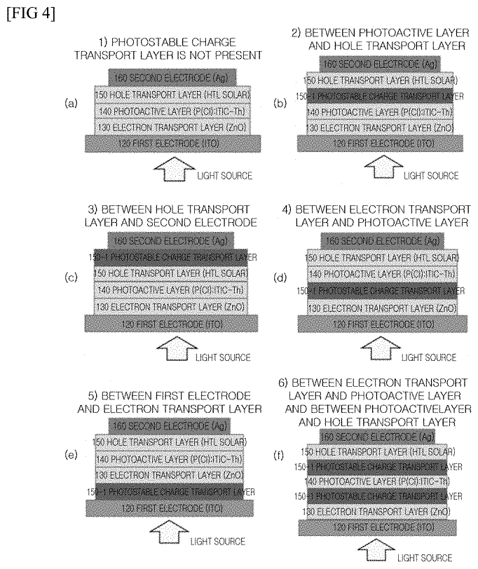

In addition, the solar cell in which only the hole transport of the layer single layer of Comparative Example 4 was introduced (see FIG. 4A) exhibited the energy conversion efficiency of 5.6% and the efficiency reduction rate of 22.22%. The solar cell in which the dual layer including the photostable charge transport layer of Example 4 was introduced between the photoactive layer and the hole transport layer (see FIG. 4B) exhibited the energy conversion efficiency of 8.1% and the efficiency reduction rate of 4.70%. In addition, the solar cell including the photostable charge transport layer of Example 5 between the electron transport layer and the photoactive layer (see FIG. 4D) exhibited the energy conversion efficiency of 7.1% and the efficiency reduction rate of 8.97%. In addition, the solar cell including the photostable charge transport layer of Example 6 introduced between the electron transport layer and the photoactive layer and between the photoactive layer and the hole transport layer (see FIG. 4F) exhibited the energy conversion efficiency of 7.4% and the efficiency reduction rate of 5.12%. As described above, the result was obtained such that the photostability was significantly improved in the solar cell in which the photostable charge transport layer was introduced between the photoactive layer and the hole transport layer and between the photoactive layer and the electron transport layer. However, the organic solar cell in which the photostable charge transport layer was introduced at another position exhibited the efficiency reduction rate of 10% or more, and thus the result was obtained such that the photostability was degraded.

In addition, the solar cell in which only the hole transport of the single layer of Comparative Example 8 was introduced exhibited the energy conversion efficiency of 7.9% and the efficiency reduction rate of 18.55%. The solar cell including the photostable charge transport layer and the hole transport layer of Example 8, specifically, in which the dual layer including the tungsten-based photostable charge transport layer and the hole transport layer was introduced, exhibited the energy conversion efficiency of 9.1% and the efficiency reduction rate of 14.15%. In addition, the solar cell in which the dual layer including the molybdenum-based photostable charge transport layer of Example 9 was introduced exhibited the energy conversion efficiency of 9.7% and the efficiency reduction rate of 9.34%. As described above, the result was obtained such that photostability was significantly improved in the solar cell in which the photostable charge transport layer was introduced. In addition, when the energy level of the donor polymer of the photoactive layer is varied, the performance may be exhibited differently according to the introduction of the hole transport layer and the photostable charge transport layer.

<Test Result of Long-Term Stability>

FIG. 14A is a graph showing test results of long-term stability of the organic solar cells of Example 1 and Comparative Example 1. Referring to FIG. 14A, after about 1,000 hours elapsed, the solar cell in which only the hole transport layer single layer of Comparative Example 1 was introduced exhibited the energy conversion efficiency of 4.1% and the efficiency reduction rate of 49.38%. The solar cell having the dual layer structure in which the photostable charge transport layer of Example 1 was introduced exhibited the energy conversion efficiency of 8.1% and the efficiency reduction rate of 12.90%. The result was obtained such that the photostability was significantly improved in the solar cell in which the photostable charge transport layer was introduced.

In addition, FIG. 14B is a graph showing test results of long-term stability of the organic solar cells of Examples 1 to 3 and Comparative Examples 1 to 3. Referring to FIG. 14B, after about 200 hours elapsed, the solar cell in which the photostable charge transport layer of Comparative Example 1 was not introduced (see FIG. 6) exhibited the energy conversion efficiency of 4.4% and the efficiency reduction rate of 38.88%. The solar cell having the dual layer structure in which the photostable charge transport layer of Example 1 was introduced between the photoactive layer and the hole transport layer (see FIG. 7) exhibited the energy conversion efficiency of 7.8% and the efficiency reduction rate of 11.36%. In addition, the solar cell in which the photostable charge transport layer of Example 2 was introduced between the electron transport layer and the photoactive layer (see FIG. 9) exhibited the energy conversion efficiency of 6.0% and the efficiency reduction rate of 15.49%. In addition, the solar cell including the photostable charge transport layer of Example 3 introduced between the electron transport layer and the photoactive layer and between the photoactive layer and the hole transport layer (see FIG. 3F) exhibited the energy conversion efficiency of 6.1% and the efficiency reduction rate of 16.43%. As described above, the result was obtained such that the long-term stability was significantly improved in the solar cell in which the photostable charge transport layer was introduced between the photoactive layer and the charge transport layer. Meanwhile, the organic solar cell in which the photostable charge transport layer was introduced at another position exhibited the efficiency reduction rate of 30% or more, and thus the result was obtained such that the long-term stability was degraded.

FIG. 15A is a graph showing test results of long-term stability of the organic solar cells of Example 4 and Comparative Example 4. Referring to FIG. 15A, after about 1,000 hours elapsed, the solar cell in which only the hole transport layer single layer of Comparative Example 4 was introduced exhibited the energy conversion efficiency of 5.4% and the efficiency reduction rate of 43.15%. The solar cell having the dual layer structure in which the photostable charge transport layer of Example 4 was introduced exhibited the energy conversion efficiency of 8.1% and the efficiency reduction rate of 19.00%. The result was obtained such that the long-term stability was significantly improved in the solar cell in which the photostable charge transport layer was introduced.

FIG. 15B is a graph showing test results of long-term stability of the organic solar cells of Examples 4 to 6 and Comparative Examples 4 to 6. Referring to FIG. 15B, after about 200 hours elapsed, the solar cell in which the photostable charge transport layer of Comparative Example 4 was not introduced (see FIG. 12) exhibited the energy conversion efficiency of 4.7% and the efficiency reduction rate of 34.72%. The solar cell having the dual layer structure in which the photostable charge transport layer of Example 4 was introduced between the photoactive layer and the hole transport layer (see FIG. 13) exhibited the energy conversion efficiency of 7.5% and the efficiency reduction rate of 11.76%. In addition, the solar cell in which the photostable charge transport layer of Example 5 was introduced between the electron transport layer and the photoactive layer (see FIG. 15b) exhibited the energy conversion efficiency of 6.5% and the efficiency reduction rate of 16.67%. In addition, the solar cell including the photostable charge transport layer of Example 6 introduced between the electron transport layer and the photoactive layer and between the photoactive layer and the hole transport layer (see FIG. 17) exhibited the energy conversion efficiency of 6.4% and the efficiency reduction rate of 17.94%. The result was obtained such that the long-term stability was significantly improved in the solar cell in which the photostable charge transport layer was introduced between the photoactive layer and the charge transport layer. Meanwhile, the organic solar cell in which the photostable charge transport layer was introduced at another position exhibited the efficiency reduction rate of 30% or more, and thus the result was obtained such that the long-term stability was degraded.

As described above, it can be seen that the organic solar cell according to the present invention includes the photostable charge transport layer introduced between the photoactive layer and the hole transport layer, introduced between the photoactive layer and the electron transport layer, and introduced between the photoactive layer and the hole transport layer and between the photoactive layer and the electron transport layer, thereby exhibiting high photostability and high durability (long-term stability). Specifically, the organic solar cell of the present invention may have high photostability and high durability by adjusting the position of the photostable charge transport layer.

### INDUSTRIAL APPLICABILITY

According to an organic solar cell according to the present invention, a photostable charge transport layer is included in one surface or two surfaces of the photoactive layer so that the organic solar cell having enhanced charge transport capability, improved photostability without an external protective film, and high durability can be provided. Therefore, it is possible to manufacture the organic solar cell with a structure of high efficiency and enhanced photostability without a process of bonding a protective glass and a protective film so that there is an advantage of significantly contributing to commercialization of a next-generation solar cell.

1. An organic solar cell comprising:
a first electrode;
a first charge transport layer;
a photoactive layer;
a second charge transport layer; and
a second electrode,
wherein a photostable charge transport layer is included in one surface or two surfaces of the photoactive layer, and
the photostable charge transport layer contains a metal oxide.

2. The organic solar cell of claim 1, wherein the photostable charge transport layer is involved at a position between the first charge transport layer and the photoactive layer, involved at a position between the second charge transport layer and the photoactive layer, or involved at each of the positions.

3. The organic solar cell of claim 1, wherein the metal oxide includes one or more selected from the group consisting of tungsten oxide, molybdenum oxide, cobalt oxide, and copper oxide.

4. The organic solar cell of claim 1, wherein an amount of the metal oxide of the photostable charge transport layer ranges from 1 g/cm³ to 10⁴ g/cm³.

5. The organic solar cell of claim 1, wherein the photoactive layer includes one or more selected from the group consisting of poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophendiyl]](PTB7), poly([2,6′-4,8-di(5-ethylhexylthienyl)benzo[1,2-b:3,3-b]dithiophene]{3-fluoro-2[(2-ethyl Hexyl)carbonyl]thieno[3,4-b]thiophendiyl})(PTB7-Th), poly[(2,6-(4,8-bis(5-(2-ethylhexyl)thiophene)-2-yl)-benzo[1,2-b :4,5-b′]dithiophene))-alt-(5,5-(1′,3′-di-2-thienyl-5′,7′-bis(2-ethylhexyl)benzo[1,2′-c:4′,5′-c′]dithiophene-4,8-dione)](PBDB-T), an SMD2 copolymer, a P(Cl)-based copolymer, and a P(Cl—Cl)-based copolymer as an electron donor.

6. The organic solar cell of claim 1, wherein the photoactive layer includes one or more selected from the group consisting of phenyl-C₆₁-butyrate methyl ester (phenyl-C61-butyric acid methyl ester or methyl[6,6]-phenyl-c61-butyrate) (PC₆₁BM), phenyl-C₇₁-butyrate methyl ester (phenyl-C71-butyric acid methyl ester or methyl[7,7]-phenyl-C₇₁-butyrate) (PC₇₁BM), 3,9-bis(2-methylene-(3-(1,1-dicyanomethylene)-indaone))-5,5,11,11-tetrakis(4-hexylphenyl)-dithieno[2,3-d:2′,3′-d′]-s-indaceno[1,2-b:5,6-b′]dithiophene (ITIC), 3,9-bis(2-methylene-(3-(1,1-dicyanomethylene)-indaone))-5,5,11,11-tetrakis(5-hexylthienyl)-dithieno[2,3-d:2′,3′-d′]-s-indaceno[1,2-b:5,6-b′]dithiophene (ITIC-Th), 2,7-bis(3-dicyanomethylene-2Z-methylene-indan-1-one))-4,4,9,9-tetrahexyl-4,9-dihydro-s-indaceno[1,2-b:5,6-b′]dithiophene (IDIC), and 3,9-bis(2-methylene-((3-(1,1-dicyanomethylene)-6,7-difluoro)-indaone))-5,5,11,11-tetrakis(4-hexylphenyl)-dithieno[2,3-d:2′,3′-d′]-s-indaceno[1,2-b:5,6-b′]dithiophene (ITIC-4F) as an electron acceptor.

7. A method of manufacturing an organic solar cell, comprising:
mixing a metal oxide precursor with a solvent and preparing a solution for a photostable charge transport layer; and
applying the solution for a photostable charge transport layer onto one surface or two surfaces of a photoactive layer to form a photostable charge transport layer.

8. The method of claim 7, wherein the preparing of the solution for a photostable charge transport layer includes mixing the metal oxide precursor with the solvent at a concentration ranging from 1 mg/ml to 10 mg/ml.

9. The method of claim 7, wherein the metal oxide precursor includes one or more selected from the group consisting of a tungsten powder, tungsten alkoxide, a tungsten carbonyl complex, tungsten ethoxide (tungsten(V,VI) ethoxide), halogenated tungsten, tungsten hydroxide, a molybdenum powder, molybdenum alkoxide, a molybdenum carbonyl complex, molybdenum sulfide, ammonium heptamolybdate tetrahydrate, a cobalt powder, cobalt alkoxide, a cobalt carbonyl complex, cobalt halide, cobalt acetate, a copper powder, copper alkoxide, a copper carbonyl complex, halogenated copper, copper nitrate, copper hydroxide, copper carbonate, a nickel powder, nickel alkoxide, a nickel carbonyl complex, halogenated nickel, nickel sulfide, and nickel hydroxide.

10. The method of claim 7, wherein the formation of the photostable charge transport layer includes applying the solution for a photostable charge transport layer onto the one surface or two surfaces of the photoactive layer using a spin coating method or a slot-die coating method.

11. The method of claim 7, wherein the formation of the photostable charge transport layer further includes performing heat treatment at a temperature ranging from 80° C. to 200° C. before and after the formation of the photostable charge transport layer.

12. The method of claim 10, wherein the formation of the photostable charge transport layer includes spin coating with the solution for a photostable charge transport layer at a speed of 1000 rpm to 4000 rpm.

13. The method of claim 10, wherein the formation of the photostable charge transport layer includes slot-die coating with the solution for a photostable charge transport layer at a discharge amount of 0.1 to 1.0 ml/min and a speed of 0.1 to 1.0 m/min.

14. The method of claim 7, wherein the formation of the photostable charge transport layer includes applying the solution for a photostable charge transport layer onto a first charge transport layer or applying the solution for a photostable charge transport layer onto the photoactive layer before forming a second charge transport layer.
